(19) United States
(12) Patent Application Publication
(10) Pub. No.: US 2022/0404413 A1
(43) Pub. Date: Dec. 22, 2022

(54) METHOD FOR ANALYZING AN ELECTRICAL CIRCUIT

(71) Applicant: Robert Bosch GmbH, Stuttgart (DE)

(72) Inventors: Benedikt Stein, Stuttgart (DE); Jan Krummenauer, Remshalden (DE); Nesrine Kammoun, Stuttgart (DE)

(21) Appl. No.: 17/843,599

(22) Filed: Jun. 17, 2022

(30) Foreign Application Priority Data
Jun. 21, 2021 (DE) 10 2021 206 323.3

(51) Int. Cl. G01R 31/28

(52) U.S. Cl. CPC G01R 31/2836

(57) ABSTRACT

A method for analyzing an electrical circuit. The method includes procuring one or multiple netlists(s) of the circuit; supplying the one or multiple netlist(s) to a classification model; and mapping, by the classification model, one or multiple of the connection(s) included in the netlist or netlists onto one or multiple net type(s) from a predefined selection of net types.

### CROSS REFERENCE

The present application claims the benefit under 35 U.S.C. § 119 of German Patent Application No. DE 10 2021 206 323.3 filed on Jun. 21, 2021, which is expressly incorporated herein by reference in its entirety.

### FIELD

The present invention relates to the analysis of electrical circuits based on netlists, in particular, for the purposes of the circuit design leading up to the manufacture and the troubleshooting process in previously manufactured circuits.

### BACKGROUND INFORMATION

The development of electrical circuits typically takes place in two phases. Initially, planning occurs at an abstract level as to which terminals (pins) of which components are to be connected to one another in each case for the circuit to be able to fulfill its desired function. This planning may be recorded in netlists. In the second phase, the circuit is designed based on the netlists so that a specific planning arises for a two-dimensional or three-dimensional arrangement of components and connections between these components. Based on this specific planning, the circuit may be manufactured, for example by applying strip conductors and components onto a circuit board.

Even though a plurality of software tools is already available, in particular, for the design of circuits, the development process still includes a lot of human work.

PCT Patent Application No. WO 2020/234 754 A1 describes a method with the aid of which a classification of the circuit may be carried out from a mapping of the circuit layout. Further general related art on the classification of circuits and/or the components contained therein is provided in China Patent Application No. CN 109 918 523 A and U.S. Patent Application Publication No. US 2019/392 322 A1.

### SUMMARY

Within the scope of the present invention, a method for analyzing an electrical circuit is provided. In accordance with an example embodiment of the present invention, in the method, one or multiple netlists(s) of the circuit is/are procured. These netlists in each case include connections between terminals (pins) of components. In the method, pins at different components, but also different pins at one and the same component, may be connected to one another.

The one or multiple netlist(s) is/are supplied to a classification model. This may, in particular, be a machine learning model, for example.

A machine learning model shall, in particular, be understood to mean a model which embodies a function parameterized with adaptable parameters, with great power for generalization. The parameters may, in particular, be adapted during a supervised training of a model in such a way that, when training input data are input into the model, associated setpoint output data are reproduced as well as possible. As an alternative or in combination therewith, the parameters may be trained during a semi-supervised training with the support of an engineer who, for example, corrects selectively wrong or improper outputs of the model.

Examples of machine learning models are neural networks, Bayesian models, logistic regression models, decision trees, XGBoost, as well as graph-based models.

In accordance with an example embodiment of the present invention, one or multiple of the connection(s) included in the netlists is/are mapped by the classification model onto one or multiple net type(s) from a predefined selection of net types. This net type may, in particular, indicate, for example,

a function and/or a configuration of the connection in the circuit, and/or

the affiliation of the connection with a functional module of the circuit, and/or

a provided voltage level of the connection, and/or

the use of the connection for analog or digital signal transmission, and/or

a speed class of a digital data transmission via the connection, and/or

a frequency range of an analog signal transmitted via the connection, and/or

a communication standard used on the connection, and/or

a categorization of the connection with respect to safety relevance.

The connections are thus annotated with one or multiple property/properties which they have in the context of the electrical circuit. This is a great help for the circuit design, but also for the troubleshooting process. In this way, for example, a visualization of a planned or existing implementation of the circuit as a two-dimensional or three-dimensional arrangement having the aforementioned properties may be enhanced. In such a representation, in particular, certain errors in the circuit design which may result in an impairment of the functional capability or even the safety are directly noticeable.

This may be illustrated, for example, based on the example of a Geiger counter for the measurement of radioactive radiation. Such a device includes a so-called counter tube in which an incoming gamma quantum locally ionizes a counter gas. To convert this ionization into an electrical signal, the counter tube must be operated at a high DC voltage of several hundred volts, which is generated using a special circuit made up of a rechargeable battery voltage in the range of 12 volts. A further circuit for the signal evaluation, in contrast, is directly operated with the rechargeable battery voltage. For directly charging the device at the outlet, additionally a power supply unit including corresponding charging electronics is needed. The seemingly simple device thus already includes three different voltage levels and two voltage transformers for transitions from one voltage level to the other. When the connections are now classified by the classification model according to voltage levels, it is immediately apparent in a graphical representation of the circuit, for example, where which voltage prevails in the device. When a high voltage-carrying connection was now planned too close to a 12 volt-carrying connection, for example during the automated circuit design with the aid of software, because this part is particularly short or advantageous in another respect, this may be recognized and corrected.

In this example, the classification model may have learned, for example during training, that a certain interconnection of components has the function of a voltage transformer, and may thus recognize the voltage transformer situated between the rechargeable battery and the counter tube as such a voltage transformer. For this reason, in addition to at least one connection, a type of a component connected to this connection, and/or a function of the pin of the component to which the connection is connected, is/are advantageously supplied to the classification model. This information may already be included in the netlists, but it may also be separately supplied to the classification model.

The type of the component and/or the function of the pin may, in particular, be ascertained, for example, from

at least one assembly list of the circuit, and/or

at least one component grouping of the circuit, and/or

at least one data sheet or one other instruction sheet of a component, and/or

at least one analytical result of a further analytical model.

In this way, it is possible to use existing primary information sources without a manual processing which is potentially prone to errors.

A further frequently occurring problem in electrical circuits is cross-talk between connections which transfer high-frequency digital or analog signals. To find trouble spots in the circuit in this regard, an overview is required as to which connections are operated at which frequencies. The classification model may, for example, ascertain the circuit pattern of an oscillator or a filter for this purpose. Based on the structure of the circuit, the classification model could then ascertain the frequency class (for example high-speed or not high-speed). If, for example, a high pass filter is recognized, the circuit is a high-speed circuit since low-frequency signals would not be able to pass the filter.

The division of the connections into net types, however, may not only be utilized to facilitate a visual analysis of the circuit for design errors. Rather, the information thus gained and present in machine-readable form may also be utilized during the automated check of the layout and/or design of the circuit. In one particularly advantageous embodiment, the layout and/or the design of the circuit is thus checked for conformity using a predefined rule set, taking at least one of the ascertained net types into consideration.

Precisely this intermeshing between an analysis of the netlists on the one hand, and checking the design on the other hand, mitigates the fundamental problem that the division of the circuit development into two parts, as mentioned at the outset, impedes the exchange of information to a certain extent. Those who, proceeding from a notion about the function of the circuit, create netlists do not yet think at that moment about the implementability in the circuit design. When the circuit is designed proceeding from netlists, these netlists are accepted as given, but it is difficult to take the originally intended function of the circuit into consideration as an additional boundary condition.

It is also possible, for example, to retrieve checklists or workflows in response to a connection belonging to a certain net type. With this, for example, a circuit designer who designs the circuit himself or herself or checks a circuit design created using software, may be reminded of all prerequisites and properties which are associated with the particular net type. For example, it is possible that a certain protocol of checks is to be completed in each case for connections which are used for digital data transmission at a particularly high speed, or for safety relevant connections. In that precisely these connections are identified using the analysis, it is possible to focus the complexity for the additional checks only on the parts of the circuit where it is truly needed.

Particularly advantageously, in accordance with an example embodiment of the present invention, at least one rule of the rule set includes that connections of two predefined net types

must not have any electrical contact with one another, and/or

must not cross one another, and/or

must extend at a minimum distance with respect to one another, and/or

must be insulated from one another by insulation.

Violations of these rules are frequent causes for impairments of the functional capability or even the safety of circuits.

In another advantageous embodiment of the present invention, the electrical circuit is divided into netlists in such a way that each netlist relates to no more than a predefined number of connected components. In this way, the size of the necessary classification model, such as, for example, of a neural network, may be kept smaller. For establishing as to which net types certain connections belong to, usually no global overview of the entire analyzed circuit is necessary, but the local context is sufficient. In the example of the Geiger counter mentioned at the outset, for example, the function of connections in the circuit for signal evaluation is not dependent on the specific configuration of the power supply unit and of the charging electronics for charging the rechargeable battery.

As mentioned at the outset, the above-described method may also be used for troubleshooting in a finished electrical circuit. In more complex devices, it is usually not practical to simply test all components and connections starting at the voltage source. Instead, it is necessary to limit the error to certain subareas of the circuit and to test components and connections in greater detail in these subareas.

The present invention therefore also provides a method for troubleshooting, or for supporting the troubleshooting process, in an electrical circuit. In accordance with an example embodiment of the present invention, in this method, initially at least one hypothesis is established for the error cause. This hypothesis may, in particular, be motivated by the symptoms of the malfunction to be eliminated, for example.

When a device, for example, no longer responds to anything and no longer shows any signs of life, a plausible hypothesis is that the power supply of the device is disrupted in a central location. In contrast, when sub-functions are still preserved, the error is rather not attributable to the central power supply.

The circuit is analyzed using the above-described method. The assignments of connections to net types obtained in the process provide information as to which connections and components connected thereto could have something to do with the established error.

Based on the at least one hypothesis, a list of net types is thus ascertained in such a way that connections belonging to these net types, and/or the components connected to these connections, could be the cause of the sought error. The specific connections in the circuit which belong to the net types included in the list as well as the components connected to these connections are ascertained. The connections and components thus ascertained are at least preferentially checked for the presence of errors.

If it is assumed, for example, that the power supply of the circuit is disrupted in a central location, the troubleshooting process may initially be focused on those connections and components which were supposed to carry the supply voltage. This process, with high likelihood, leads to the location at which the supply voltage is either not being fed, even though it is supposed to be fed, or, for example, is being dragged down by an at least partial short circuit.

In the process, in particular, multiple hypotheses for the error cause, for example, and/or the lists of the net types, may be organized in descending order of the likelihoods with which the respective hypothesis is accurate, or with which connections of the respective net type or components connected thereto may be causative for the sought error. In this way, the expected value for the required time until the error is located is reduced.

The method for analysis may, in particular, be entirely or partially computer-implemented. The present invention thus also relates to a computer program including machine-readable instructions which, when they are executed on one or multiple computer(s), prompt the computer(s) to carry out the described method.

The present invention also relates to a machine-readable data medium and/or to a download product including the computer program. A download product is a digital product transferrable via a data network, i.e., downloadable by a user of the data network, which may be offered for immediate download in an online shop, for example.

Furthermore, a computer may be equipped with the computer program, with the machine-readable data medium and/or with the download product.

Further measures improving the present invention are shown hereafter in greater detail together with the description of the preferred exemplary embodiments of the present invention based on figures.

### BRIEF DESCRIPTION OF THE DRAWINGS

FIG. 1 shows one exemplary embodiment of method 100 for analyzing an electrical circuit 1.

FIG. 2 shows one exemplary embodiment of method 200 for troubleshooting an electrical circuit 1.

### DETAILED DESCRIPTION OF EXAMPLE EMBODIMENTS

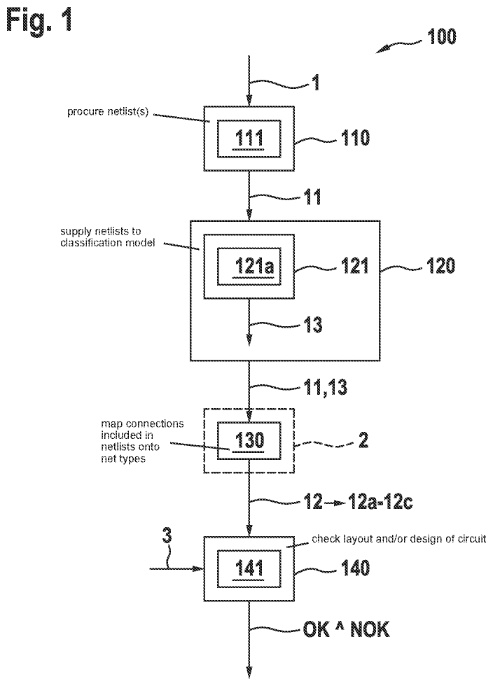

FIG. 1 is a schematic flowchart of one exemplary embodiment of method 100 for analyzing an electrical circuit 1.

In step 110, one or multiple netlists(s) 11 of circuit 1 is/are procured. In the process, according to block 111, electrical circuit 1 may be divided into netlists 11 in such a way that each netlist 11 relates to no more than a predefined number of connected components 13.

In step 120, the one or multiple netlist(s) is/are supplied to a classification model. According to block 121, in addition to at least one connection 12, a type of a component 13 connected to this connection 12, and/or a function of the pin of component 13 to which connection 12 is connected, is/are supplied to classification model 2. According to block 121a, the type of the component, and/or the function of the pin, may, in particular, be ascertained, for example, from

at least one assembly list of circuit 1, and/or

at least one component grouping of circuit 1, and/or

at least one data sheet or one other instruction sheet of a component 13, and/or

at least one analytical result of a further analytical model.

In step 130, one or multiple of connection(s) 12 included in netlist or netlists 11 is/are mapped by classification model 2 onto one or multiple net type(s) 12a through 12c from a predefined selection of net types 12a through 12c.

In step 140, the layout and/or the design of circuit 1 is checked for conformity using a predefined rule set 3, taking at least one of the ascertained net types 12a through 12c into consideration. With each rule, the circuit may either be conforming (OK) or non-conforming (NOK). According to block 141, at least one rule of rule set 3 may include that connections 12 of two predefined net types 12a through 12c

must not have any electrical contact with one another, and/or

must not cross one another, and/or

must extend at a minimum distance with respect to one another, and/or

must be insulated from one another by insulation.

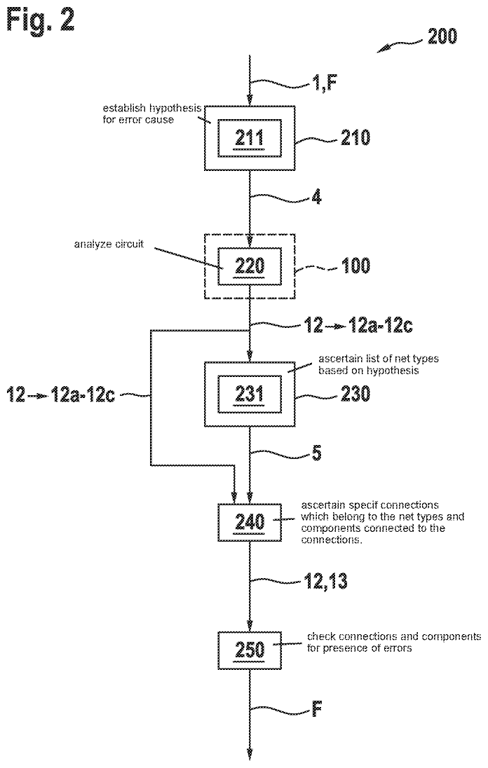

FIG. 2 is a schematic flowchart of one exemplary embodiment of method 200 for troubleshooting in an electrical circuit 1 which is subject to an initially unknown error F.

In step 210, at least one hypothesis 4 for the error cause is established.

According to block 211, multiple hypotheses 4 may be established and may be organized in descending order of the likelihoods with which they accurately describe the error cause.

In step 220, circuit 1 is analyzed using the above-described method 100.

In step 230, a list 5 of net types 12a through 12c is ascertained based on the at least one hypothesis 4. These net types 12a through 12c are selected in such a way that connections 12 belonging precisely to these net types 12a through 12c, and/or components 13 connected to these connections 12, may be causative for the sought error F.

According to block 231, list 5 of net types 12a through 12c may be organized in descending order of the likelihoods with which connections 12 of the respective net type 12a through 12c, or components 13 connected thereto, are causative for the sought error F.

In step 240, the specific connections 12 in circuit 1 which belong to net types 12a through 12c included in list 5 as well as components 13 connected to these connections 12 are ascertained.

In step 250, connections 12 and components 13 thus ascertained are at least preferentially checked for the presence of errors. This means that it is also possible to check other connections and components, but the ascertained connections 12 and components 13 are preferred.

What is claimed is:

1. A method for analyzing an electrical circuit, comprising the following steps:
procuring one or multiple netlists of the circuit;
supplying the one or multiple netlists to a classification model; and
mapping, by the classification model, one or multiple of connections included in the one or multiple netlists onto one or multiple net types from a predefined selection of net types.

2. The method as recited in claim 1, wherein at least one net type indicates:
a function and/or a configuration of a connection in the circuit, and/or
an affiliation of the connection with a functional module of the circuit, and/or
a provided voltage level of the connection, and/or
a use of the connection for analog or digital signal transmission, and/or
a speed class of a digital data transmission via the connection, and/or
a frequency range of an analog signal transmitted via the connection, and/or
a communication standard used on the connection, and/or
a categorization of the connection with respect to safety relevance.

3. The method as recited in claim 1, wherein, in addition to at least one connection, a type of a component connected to the at least one connection, and/or a function of a pin of a component to which the connection is connected, is supplied to the classification model.

4. The method as recited in claim 3, wherein the type of the component, and/or the function of the pin, is ascertained from:
at least one assembly list of the circuit, and/or
at least one component grouping of the circuit, and/or
at least one data sheet or one other instruction sheet of a component, and/or
at least one analytical result of a further analytical model.

5. The method as recited in claim 1, wherein a layout of the circuit and/or a design of the circuit is checked for conformity using a predefined rule set, taking at least one of the mapped net types into consideration.

6. The method as recited in claim 5, wherein at least one rule of the rule set includes that connections of two predefined net types:
must not have any electrical contact with one another, and/or
must not cross one another, and/or
must extend at a minimum distance with respect to one another, and/or
must be insulated from one another by insulation.

7. The method as recited in claim 1, wherein the electrical circuit is divided into netlists in such a way that each netlist of the netlists relates to no more than a predefined number of connected components.

8. A method for troubleshooting an electrical circuit, comprising the following steps:
establishing at least one hypothesis for a cause of an error;
analyzing the circuit by:
procuring one or multiple netlists of the circuit,
supplying the one or multiple netlists to a classification model, and
mapping, by the classification model, one or multiple of connections included in the one or multiple netlists onto one or multiple net types from a predefined selection of net types;
based on the at least one hypothesis, ascertaining a list of net types in such a way that connections belonging to the net types, and/or components connected to the connections, may be causative for the error;
ascertaining specific connections in the circuit which belong to the net types included in the list as well as components connected to the specific connections; and
checking the ascertained specific connections and components for a presence of errors.

9. The method as recited in claim 8, wherein multiple hypotheses for the cause of the error, and/or the list of the net types, are organized in descending order of likelihoods: (i) with which the respective hypothesis is accurate, or (ii) with which connections of the respective net type or components connected the net type are causative for the error.

10. A non-transitory machine-readable data medium on which is stored a computer program for analyzing an electrical circuit, the computer program, when executed by a computer, causing the computer to perform the following steps:
procuring one or multiple netlists of the circuit;
supplying the one or multiple netlists to a classification model; and
mapping, by the classification model, one or multiple of connections included in the one or multiple netlists onto one or multiple net types from a predefined selection of net types.

11. One or multiple computers configured to analyze an electrical circuit, the one or multiple computers configured to:
procure one or multiple netlists of the circuit;
supply the one or multiple netlists to a classification model; and
map, by the classification model, one or multiple of connections included in the one or multiple netlists onto one or multiple net types from a predefined selection of net types.
